(19) United States
(12) Patent Application Publication
(10) Pub. No.: US 2024/0158949 A1
(43) Pub. Date: May 16, 2024

(54) STRUCTURES FOR COMMUNICATION, MONITORING AND CONTROL OF CORROSIVE PROCESS ENVIRONMENTS AT HIGH PRESSURE AND HIGH TEMPERATURE

(71) Applicant: SLT Technologies, Inc., Los Angeles, CA (US)

(72) Inventor: Paul M. VON DOLLEN, Brush Prairie, WA (US)

(21) Appl. No.: 18/501,951

(22) Filed: Nov. 3, 2023

Related U.S. Application Data
(60) Provisional application No. 63/424,792, filed on Nov. 11, 2022.

(51) Int. Cl. C30B 7/10; B01D 53/22; B01D 71/02

(52) U.S. Cl. CPC C30B 7/105; B01D 53/22; B01D 71/02231; C30B 29/403

(57) ABSTRACT

Embodiments of disclosure include an apparatus for high-temperature crystal growth. The apparatus can include a pressure vessel having a capsule that has an interior surface that defines an internal capsule volume, a fill tube that comprises an outer surface and an inner surface, wherein an interior fill tube volume defined by the inner surface is in fluid communication with the internal capsule volume of the capsule, a sleeve axially surrounding the outer surface of the fill tube, wherein the sleeve is configured to support the outer surface of the fill tube, along the length of the fill tube, during a high-temperature crystal growth process, and a manifold comprising an interior manifold volume that is in fluid communication with the interior fill tube volume of the fill tube.

### CROSS-REFERENCE TO RELATED APPLICATIONS

This application claims priority to U.S. Provisional Application Ser. No. 63/424,792 filed Nov. 11, 2022, which is herein incorporated by reference in its entirety.

### BACKGROUND

### Field

The present disclosure generally relates to a crystal growth apparatus and method of processing the same, and more particularly, to real time monitoring and feedback of process variables during a crystal growth process.

### Description of Related Art

The current apparatus for high-temperature acidic ammonothermal crystal growth involves a sealed pressure vessel that is configured to sustain high processing pressures. That is, a pressure vessel has no capability for direct measurement or monitoring of the process fluid pressure during the crystal growth process. Strain gauges on load-bearing members such as tie rods can be used to infer and model the internal process pressure, but calibration and measurement accuracy are challenging in the high temperature and high pressure environment, and thus proper characterization of the process likely requires multiple distributed gauges, which is cumbersome. Furthermore, with a sealed pressure vessel there is no provision for reversible filling or venting of the contents used during the acidic ammonothermal crystal growth process. To relieve the pressure post-run, destructive drilling or some other mechanical breach in the hermetic boundary is required. In the current apparatus, unambiguous leak detection is also challenging due the use of only a few discrete sampling points.

Therefore, there is a need for systems and methods that allows real time monitoring and feedback of process pressure, which is a key thermodynamic quantity influencing a crystal growth process.

### SUMMARY

Embodiments of the disclosure include an apparatus for high-temperature crystal growth, comprising: a pressure vessel comprising a capsule that has an interior surface that defines an internal capsule volume; a fill tube that comprises an outer surface and an inner surface, wherein an interior fill tube volume defined by the inner surface is in fluid communication with the internal capsule volume of the capsule; a sleeve axially surrounding the outer surface of the fill tube, wherein the sleeve is configured to support the outer surface of the fill tube, along a length of the fill tube, during a high-temperature crystal growth process; and a manifold comprising an interior manifold volume that is in fluid communication with the interior fill tube volume of the fill tube.

Embodiments of the disclosure include a supported fill tube (SFT) assembly, comprising: a fill tube that comprises an outer surface and an inner surface, wherein an interior fill tube volume defined by the inner surface is in fluid communication with an internal volume of a sealed pressure vessel; a sleeve axially surrounding the outer surface of the fill tube, wherein the sleeve is configured to support the outer surface of the fill tube along a length of the fill tube; and a manifold comprising an interior manifold volume that is in fluid communication with the interior fill tube volume of the fill tube. The manifold comprises at least one of the following: a fill valve that is in fluid communication with the interior manifold volume; a selective membrane that is in fluid communication with the interior manifold volume; a pressure transducer that is in fluid communication with the interior manifold volume; and a gas reservoir. In one example, the manifold comprises a fill valve for sampling gas from the sealed pressure vessel to be analyzed; a selective membrane for selectively passing through between the manifold and the sealed pressure vessel; a pressure transducer; and/or a gas reservoir.

### BRIEF DESCRIPTION OF THE DRAWINGS

So that the manner in which the above recited features of embodiments of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A depicts a schematic cross-sectional view of a system according to one or more embodiments of the present disclosure.

FIG. 1B depicts an enlarged cross-sectional view of the circled portion of the system of FIG. 1A.

FIG. 2 depicts a schematic cross-sectional view of a pressure vessel according to one or more embodiments of the present disclosure.

FIGS. 3A, 3B, and 3C depict cross-sectional views of a supported fill tube (SFT) assembly according to one or more embodiments of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The embodiments described herein provide one or more fluid delivery and/or fluid containing components, such as a high-pressure processing vessel that includes a fill tube, which is in fluid communication with a process volume of the high-pressure processing vessel for thermal crystal growth for the entire duration of thermal crystal growth process. Such fluid communication through the fill tube allows real time monitoring and feedback of process pressure, which is a key thermodynamic quantity influencing a crystal growth process. Measuring process pressures also allows unambiguous leak detection that can be easily resolved as a decrease in the time-series value or slope of process pressure greater than some critical value. According to the embodiments described herein, the high-pressure processing vessel and fill tube is also connected to a manifold which in turn can contain any number of valves, measurement devices, or even satellite components and assemblies designed to interact with the thermal crystal growth process volume in situ.

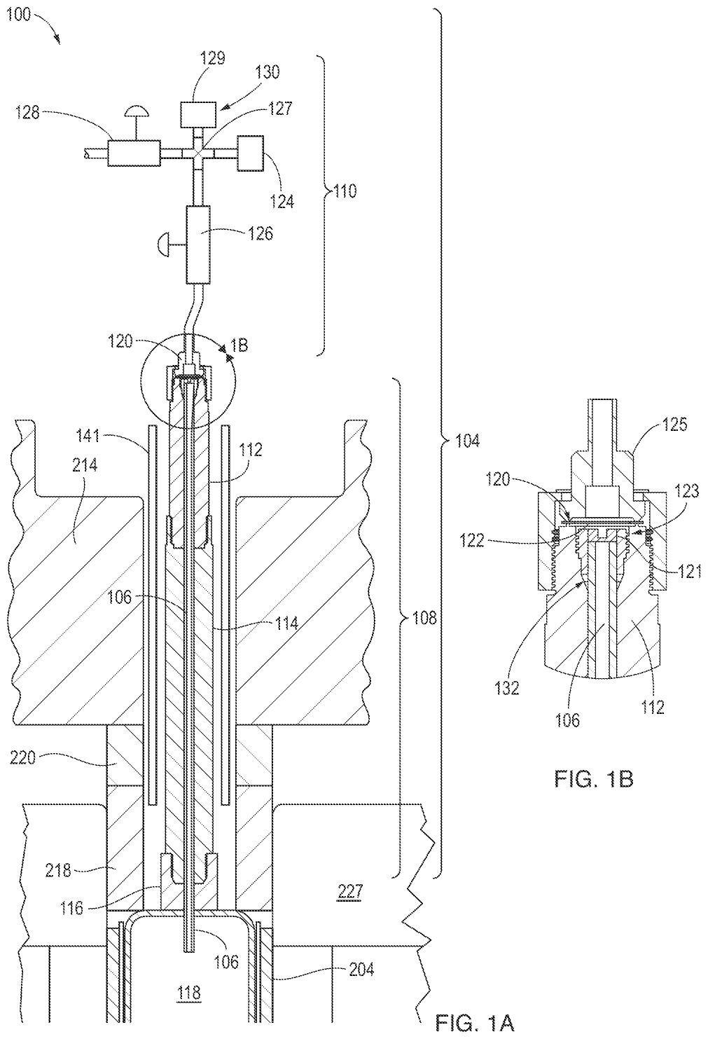

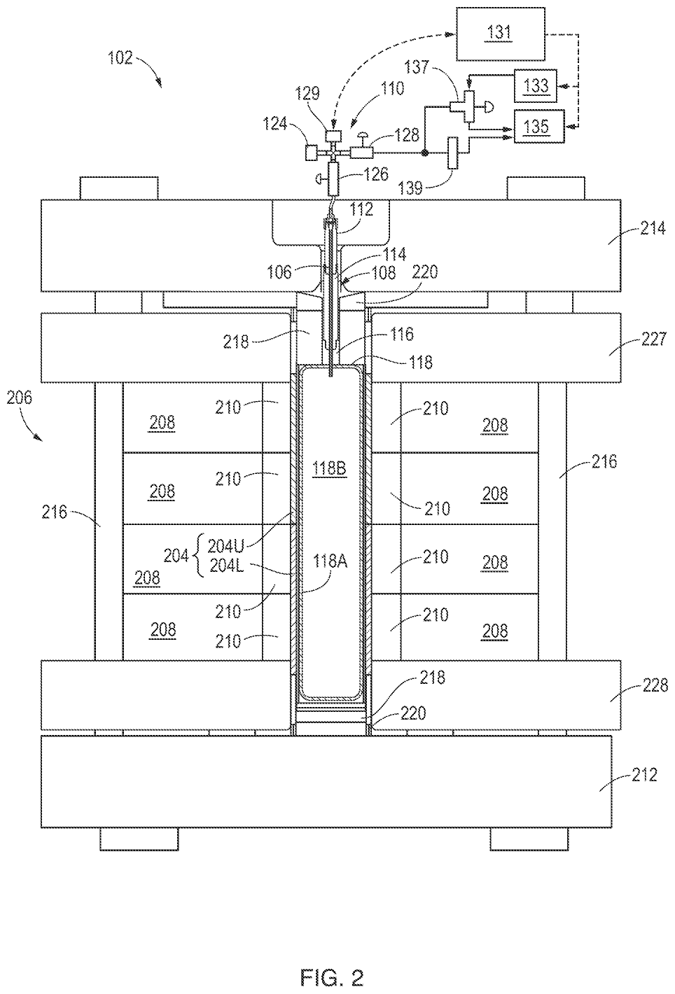

Apparatus for High-Temperature Crystal Growth FIG. 2A depicts a schematic partial cross-sectional view of an upper portion of an apparatus 100 for performing a high-temperature crystal growth process (e.g., GaN, AlN, InN, InGaN, AlGaN, and AlInGaN) that includes a portion of a pressure vessel 102, which is illustrated in FIG. 2. FIG. 1B depicts an enlarged cross-sectional view of the circled portion 1B of the apparatus 100 shown in FIG. 1A. FIG. 2 depicts a schematic cross-sectional view of a pressure vessel 102 according to one or more embodiments of the present disclosure.

The apparatus 100 includes a supported fill tube (SFT) assembly 104 and pressure vessel 102. The SFT assembly 104 includes a fill tube 106 axially surrounded by a sleeve 108 extending along the length of the fill tube 106, and a manifold 110. One end of the fill tube 106 is in fluid communication with the pressure vessel 102 and is used to introduce or fill chemicals into a process environment of the pressure vessel 102 during a pre-processing stage of a crystal growth process and fluidly communicate with the processing environment during the crystal growth process. The other end of the fill tube 106 is connected to the manifold 110, and the interior volume of the fill tube 106, which is defined by the inner surface of the fill tube 106, is in fluid communication with the interior volume of the manifold 110. In one embodiment, the sleeve 108 includes a fill tube support stem 112, a middle sleeve 114 covering a bottom of the fill tube support stem 112, and a fill-tube lower boss 116 (shown in FIG. 2) of the pressure vessel 102 covering a bottom of the middle sleeve 114. In another embodiment, the sleeve 108 only includes the fill-tube lower boss 116 and the middle sleeve 114, wherein the fill tube support stem 112 has been removed in this case, and thus the middle sleeve 114 is configured to extend from the fill-tube lower boss 116 to the manifold 110. In some embodiments, one or more of the fill tube support stem 112, a middle sleeve 114 and a fill-tube lower boss 116 of the sleeve 108 are formed from a material selected from a group of steel, low-carbon steel, SA723 steel, SA266 carbon steel, 4340 steel, A-286 steel, iron based superalloy, nickel based superalloy, cobalt based superalloy, Inconel® 718, Rene® 41, 304 stainless steel, 310 stainless steel, 316 stainless steel, 340 stainless steel, 410 stainless steel, and 17-4 precipitation hardened stainless steel, zirconium and its alloys, titanium and its alloys, and other materials commonly known as Monel®, Inconel®, Hastelloy®, Udimet® 500, Stellite®, Rene® 41, and Rene® 88. In one example, the fill tube support stem 112, a middle sleeve 114 and a fill-tube lower boss 116 of the sleeve 108 are formed from a superalloy, such as an iron based superalloy, nickel based superalloy, or cobalt based superalloy, which can include Hastelloy®, Udimet®, Stellite®, Inconel®, or Rene® alloys.

### Pressure Vessel

As shown in FIG. 2, the pressure vessel 102 includes a capsule 118. An inner volume 1186 of the capsule 118 is a process environment of the pressure vessel 102 in which a high-temperature ammonothermal crystal growth process can be performed. The fill-tube lower boss 116 is positioned over a top portion of the capsule 118. In some embodiments, the portion of the fill tube 106 extending through the fill-tube lower boss 116 is hermetically sealed to an upper portion (e.g., cap) of the capsule 118 by welding, brazing, or soldering. A hermetic seal generally includes a seal that prevents a fluid or gas from passing from one side of a seal to an opposing side of the seal. In some cases, it is desirable to perform an ASTM or ISO standard helium leak test to determine whether a sufficient hermetic seal has been created.

In general, the process environment of the pressure vessel 102 is corrosive, and thus the fill tube 106 is formed of corrosion-resistant material, such as Inconel or other noble metals, such as rhenium, ruthenium, rhodium, palladium, silver, osmium, iridium, platinum, and gold. In some embodiments, the fill tube 106 includes Inconel and the inner surface of the fill tube 106 is lined with silver-containing material. In some embodiments, the fill tube 106 is formed from a material that includes silver or a silver alloy. Since corrosion rates for most materials exposed to the chemistry of a high-pressure crystal growth process are lower or negligible at temperatures lower than the average crystal growth temperature, more material choices are available for the fill tube 106 for a crystal growth process in which the fill tube 106 and/or the manifold 110 are designed to be exposed or maintained at lower temperatures during processing due to the structural configuration of the SFT assembly 104. In some embodiments, the manifold 110 is positioned a sufficient distance from the capsule 118 to allow a temperature gradient formed along the length of the SFT assembly 104, such as the length between the capsule 118 to the manifold 110, during processing to generate a desired maximum temperature in the manifold 110 that is low enough such that significant corrosion does not occur on the exposed surfaces of the interior volume of the manifold 110 and other attached components. In one example, the crystal growth process includes an ammonothermal crystal growth process that is performed at temperatures between 400° C. and 1,500° C., such as between 600° C. and 900° C., and the process chemistries can include, but are not limited to, an ammonobasic or ammonoacidic chemistry. In some examples, the crystal growth process includes the use of a chemistry that includes one or more of F, Cl, Br, I, HF, HCl, HBr, HI, Ga, Al, In, GaN, AlN, InN, NH₃, Li, Na, K, Rb, and Cs. Additionally, materials resistant to the corrosive process environment at high temperatures typically have poor mechanical properties and are not suitable to be used for high pressure containment.

The capsule 118 may be formed of platinum, palladium, iridium, a Pt/Ir alloy, gold, or silver, titanium, rhenium, copper, iron, nickel, stainless steel, zirconium, tantalum, molybdenum, niobium, alloys thereof, and the like. The fill-tube lower boss 116, and the end plugs 218 may each be formed of mechanically robust material, such as steel, low-carbon steel, SA723 steel, SA266 carbon steel, 4340 steel, A-286 steel, iron based superalloy, nickel based superalloy, cobalt based superalloy, Inconel® 718, Rene® 41, 304 stainless steel, 310 stainless steel, 316 stainless steel, 340 stainless steel, 410 stainless steel, and 17-4 precipitation hardened stainless steel, zirconium and its alloys, titanium and its alloys, and other materials commonly known as Monel®, Inconel®, Hastelloy®, Udimet® 500, Stellite®, Rene® 41, and Rene® 88.

The capsule 118 is surrounded by a heater 204 that is surrounded by a stack of ring assemblies 206. During a high-temperature ammonothermal crystal growth process, the internal volume 1186 of the capsule 118 is heated by the heater 204 to a temperature of between about 50° C. and 1500° C., and is filled with a process fluid, such as ammonia or water, in which a mineralizer is dissolved, under a high pressure of between about 5 mega-Pascal (MP) and about 2000 MP. At these temperatures and pressures it is often desirable to cause the process gases to achieve a supercritical fluid state to enhance the crystal growth process. The internal volume 118B of the capsule 118 is defined by an interior surface 118A of the capsule 118.

The ring assemblies 206 each include an enclosure ring 208 and a ceramic ring 210 that is surrounded by the enclosure ring 208. The ring assemblies 206 may provide radial confinement for pressure generated within the capsule 118 and transmitted outward through the heater 204. The ring assemblies 206 are supported on a top end and a bottom end by ring supports 227, 228, respectively, which are used to take some of an axial load created during processing. The heater 204 may include an upper heater 204U and a lower heater 204L that are each independently controllable.

The pressure vessel 102 further includes a bottom crown assembly 212, a top crown assembly 214, and tie rod fasteners 216. The bottom crown assembly 212 and the top crown assembly 214 are configured to support the axial load generated by the pressure formed in the capsule 118 during the crystal growth process. The bottom crown assembly 212, the top crown assembly 214, and the tie rod fasteners 216 may each be formed of mechanically robust material, such as steel, low-carbon steel, SA723 steel, SA266 carbon steel, 4340 steel, A-286 steel, iron based superalloy, 304 stainless steel, 310 stainless steel, 316 stainless steel, 340 stainless steel, 410 stainless steel, 17-4 precipitation hardened stainless steel, zirconium and its alloys, titanium and its alloys, and other materials commonly known as Monel®, Inconel®, Hastelloy®, Udimet® 500, Stellite®, Rene® 41, and Rene® 88. The end plugs 218 may be formed of zirconium oxide or zirconia, and mechanically supported and radially confined by end plug jackets 220. The end plug jackets 220 may be formed of steel, stainless steel, an iron-based alloy, or a nickel-based alloy. The end plug jackets 220 may also provide mechanical support and/or axial confinement for the heater 204.

Manifold and Monitoring of Pressure Vessel

The manifold 110 can directly monitor and control process pressure in the internal volume 118B of the capsule during a high-temperature ammonothermal crystal growth process. The manifold 110 will typically include a plurality of fittings, tubing and other similar fluid delivery components, since the manifold 110 is designed, and positioned within the SFT assembly 104, for more moderate temperature service where the corrosion, due to exposure to the crystal growth process chemistry, is much reduced. The interior surfaces of the fittings, tubing and fluid delivery components generally define the interior volume of the manifold 110. The manifold 110 includes a sealing structure 120, a valve 126, a flange 125, a gasket 122, a tee 127, or a cross, coupled to the end of fill tube 106. The flange 125 may be formed integral to the manifold 110. The manifold 110 may include a gasket 122 that is disposed between the flange 125 of the manifold 110 and the upper end 123 of the fill tube support stem 112. The manifold 110 may include a pressure transducer 124, a fill valve 126, a vent valve 128, and/or sensors 129 (e.g., temperature sensor, gas composition sensors, etc.) that are all in fluid communication with the interior volume of the manifold 110. The vent valve 128 can be configured to allow the contents of the capsule 118 to be vented to an exhaust system 135 through a control valve 137, and allow the process chemistry to be delivered through the control valve 137 and to the capsule 118 by use of a fluid source 133. The vent valve 128, the fill valve 126, the pressure transducer 124, the control valve 137, and the sensors 129 can be coupled to a system controller 131 that is used to control valves and receive the inputs from the pressure transducer 124 and the sensors 129. One or more ports 130 on the manifold 110 may mount instruments or tools which can interact with the process environment of the pressure vessel 102 in situ.

Since the manifold 110 is generally positioned above the process environment of the pressure vessel 102, test charges or samples can be introduced by gravity or by a generated pressure created in the fluid source 133 during the high-temperature ammonothermal crystal growth process by actuating the various valves or other elements in or coupled to the manifold 110. Process gases can be introduced to control process pressure by opening the fill valve 126 and one or more of the fluid source 133 that includes a source or pressurized gas reservoir (not shown) through the vent valve 128 and/or exhaust system 135. Enabling the process environment of the pressure vessel 102 to communicate with a separate gas reservoir can also allow regulation of process pressures by using a pump (not shown) to directly control the pressure in the reservoir or by mechanically adjusting the volume of the reservoir.

Gases can also be sampled or removed from the internal volume 1186 of the capsule 118 by opening the fill valve 126 that is connected to a sampling or analysis volume, or a sensor 129, such as a residual gas analyzer (RGA).

Gases can be selectively passed through (e.g., removed or introduced) between the manifold 110 and the internal volume 1186 of the capsule 118 during the high-temperature ammonothermal crystal growth process by use of a selective membrane 139. In some embodiments, the selective membrane 139 is disposed within or coupled to an outlet port of the fluid source 133 that is attached to the manifold 110. In some other embodiments, the selective membrane 139 is disposed between an end of the fill tube 106 and the manifold 110. In some embodiments, the selective membrane 139 is a palladium-containing membrane, through which hydrogen gas readily diffuses whereas other gases such as nitrogen gas do not. Hydrogen gas can be selectively removed from the pressure vessel 102 by diffusion through a palladium-containing membrane to modify and control stoichiometry of the process fluid. In some embodiments, the selective membrane 139 is configured to allow a first gas (e.g., H₂) of a plurality gases (e.g., an ammonobasic or ammonoacidic crystal growth process chemistry) disposed on a first side of the selective membrane to pass to an opposing side of the membrane while preventing one or more of the other plurality of gases disposed on the first side of the selective membrane from passing to the opposing side of the membrane.

Fluid Delivery and/or Fluid Containing Components Design Examples

In some embodiments, the SFT assembly 104 is designed to avoid clogging of the fill tube 106 created by the fluid properties and corrosive nature of the crystal growth process chemistry. During a high-temperature ammonothermal crystal growth process in which the process fluid contains one or more condensable species, temperature-dependent condensation of the process fluid may occur on wetted inner surfaces of the fill tube 106 of the SFT assembly 104 where the temperature falls below a critical condensation temperature. This condensation may clog an interior of the fill tube 106 if condensation products are solid and a significant amount of the condensation products are generated, which will cause the fluid communication between the components in the SFT assembly 104 and the pressure vessel 102 to be lost or greatly decreased. A blockage created by the condensation products within the fill tube 106 and manifold 110 can cause a post-run venting process to be undesirably slow.

Therefore, in some embodiments, the fill tube 106 is configured to have an inner diameter that is large enough to avoid or reduce a continuous bridge of condensed material from the process fluid from forming, while minimizing the thermal loss through the fill tube 106 and stress induced on the upper portion of the capsule 118 during the high pressure processing. The inner diameter and wall thickness of the fill tube 106 may be selected so as to avoid an excessive amount of heat transfer from the upper portion of the capsule 118 due to the larger cross-sectional area of the tube 106 required to withstand the high pressures utilized during the growth process, and increased thermal conduction through the larger sleeve 108 and other components. In some embodiments, the fill tube 106 and the sleeve 108 are largely at a uniform temperature that is similar to temperature of process fluid within the internal volume 118B of the capsule 118. In some embodiments, the fill tube 106 has a heater 141 positioned outside of the sleeve 108 to control the temperature of the fill tube 106 and prevent clogging due to the condensation of the process fluid in the interior of the fill tube 106. The fill tube 106 and the sleeve 108 can have a temperature difference of about 400° C. between opposing ends of the sleeve 108 in cases where the heater 141 is not used, while in some cases the temperature difference can be lessened to about 20° C. between opposing ends of the sleeve 108 when a heater 141 is used. Thus, in some embodiments, the fill tube comprises a first end and a second end that is opposite to the first end, and a temperature difference formed between the first end and the second end, due to its length end-to-end, thermal properties and physical relationship to the sleeve 108 and the sleeve's thermal properties, is greater than 400° C. during a high-temperature crystal growth process. By use of the system controller 131 during one or more parts of the crystal growth process, any condensed process fluid may be preferentially heated by use of at least a portion of the heater 141 so as to decompose or desorb the solid condensate to regain fluid communication between components on either end of the fill tube 106. This heating process may be done periodically during the process to assure that fluid communication is maintained through the fill tube 106. If the fluid communication during the run is acceptable but the clogging makes the venting process too slow, the heating process may be done only at the end of the run after the process vessel 102 is cool and further condensation or clogging is not possible. In some other embodiments, a vibratory or other mechanical perturbation device (not shown) are used to actuate and/or vibrate the exterior surface of the sleeve 108 to mechanically dislodge any condensed process fluid in the interior of the fill tube 106 during or after the run.

In some embodiments, a gas or liquid chemical known to etch the condensed process fluid is supplied into the interior of the fill tube 106 to prevent a post-run venting process from being too slow. Since there is a minimal risk of contaminating the pressure vessel 102 and damaging the grown crystals post-run, a wider selection of gas or liquid chemicals can be used to remove the condensed matter. In some embodiments, the manifold 110 is removed so that a tool, such as a drill or auger, could be used to mechanically remove the condensate from the interior of the fill tube 106.

### Fluid Delivery and/or Fluid Containing Components Design for Mechanical Support

For mechanical support of the fill tube 106, the fill tube 106 is disposed at the inner surface of the sleeve 108. Since the fill tube 106 is hermetically sealed to the upper portion of the capsule 118 by use of a welded or brazed joint, the sleeve 108, which are used to structurally support the fill tube 106 when a high pressure is formed inside the fill tube 106, the sleeve 108 can be assembled from one or more components with non-hermetic sealed joints. This wetted and non-wetted structure created by the design of the fill tube 106 and sleeve 108 reduces the design complexity and enhances ease of assembly and dis-assembly/reuse.

Under process conditions, the outer surface of the fill tube 106 and an inner surface of the sleeve 108 are in close contact or direct contact due to the high pressure acting on the inner surface of the fill tube 106. In some embodiments, the sleeve 108 is formed of one or more open cylinders or tubes with a complete (non-split) circumference, and slipped over the fill tube 106 to form a concentric arrangement. In this configuration, the assembly requires a finite radial gap between the outer surface of the fill tube 106 and the inner surface of the sleeve 108, which can be minimized to less than 0.005 inches (0.13 mm). In alternative embodiments, the sleeve 108 includes two or more open half cylinders which are positioned over the outer diameter of the fill tube 106 from either side. In this case, the radial gap between the fill tube 106 and the sleeve 108 can be vanishingly small, e.g., less than about 0.001 inches (0.03 mm). Using split sleeves also requires either a separate outer sleeve which has an integral circumference or a method for mechanically fastening the two split halves together prior to pressurization so that the radial load created by the high pressure formed within the fill tube 106 during processing can be supported.

### Hermetic Seals of Fill Tube

The sleeve 108 is formed of a mechanically robust material, such as Inconel, or titanium-zirconium-molybdenum (TZM), and extends the entire length of the fill tube 106 such that the radial and axial strain experienced by the fill tube 106 during high the pressure processing is limited and the fill tube 106 remains hermetically sealed along its length for the entire crystal growth process which can last for days, weeks or even two or more months. The sleeve 108 may be attached to or integrated with other mechanically robust external structural supporting components (not shown (e.g., clamps)) to improve the assembly or handling of the entire SFT assembly 104.

The sleeve 108 formed of mechanically robust structure also provides a structural mounting point for transitioning between the fill tube 106 to the upper portion of the capsule 118 and the manifold 110. The transition between the manifold 110 and the fill tube 106 requires a direct single hermetic seal to be formed between the fill tube 106 and the manifold 110, or an indirect double hermetic seal between the fill tube 106 and the fill tube support stem 112 and also between the fill tube support stem 112 and the manifold 110.

### Direct Single Hermetic Seal Configuration

Creating a single hermetic seal between the fill tube 106 and the manifold 110 can be accomplished by welding, flaring, drawing, or the like the fill tube 106 to the sealing structure 120 to the manifold 110 and then using standard connection fittings, such as VCR®/face seal fittings or other methods to seal, to the sealing structure 120 to the manifold 110. The sealing structure 120 may include a flange 125 and/or a gasket 122 that is disposed between the flange 125 and the fill tube support stem 112. In this case the manifold 110 can be mechanically joined to the sleeve 108, however, in this case the joint between the manifold 110 and the sleeve 108 does not need to form a hermetic seal. This arrangement has a practical downside in that once the sealing structure 120 is introduced no further components can be introduced axially along the fill tube length with a close axial fit to the fill tube 106. That is, the entire SFT assembly 104 needs to be constructed and cannot subsequently be de-constructed without removing the sealing structure 120. Another practical downside is that the sealing structure 120 fixes the total length and position of the fill tube 106 relative to the sleeve 108 and the manifold 110. So subsequent thermal expansion differences introduce stress in the region between the sealing structure 120 and the fill tube 106.

### Indirect Double Hermetic Seal

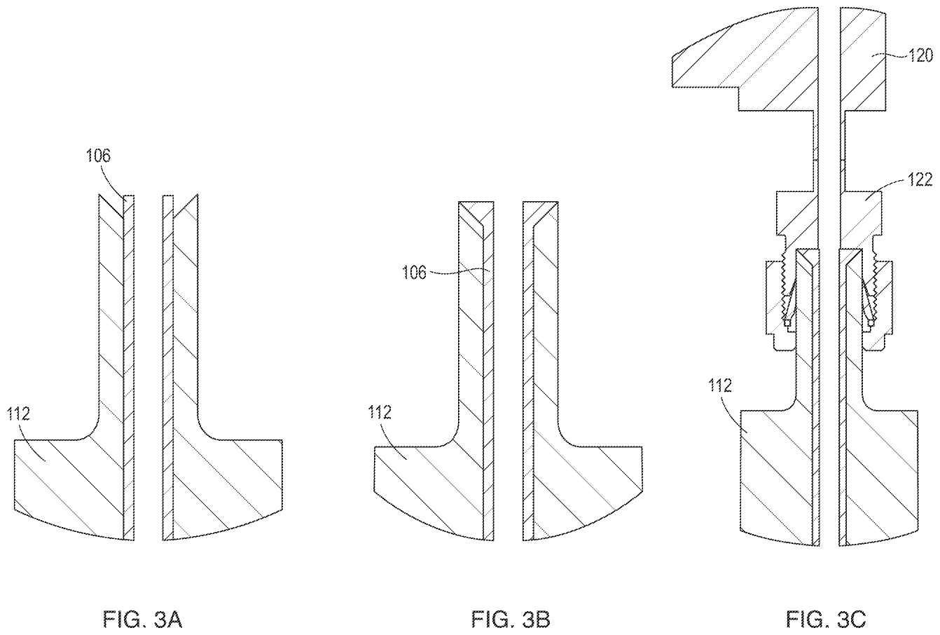

Creating two hermetic seals, one between the fill tube 106 and the fill tube support stem 112 and another between the fill tube support stem 112 and the manifold 110, can be accomplished in a number of ways. In some embodiments, the fill tube 106 is inserted inside an opening of the fill tube support stem 112 as shown in FIG. 3A, and at least a portion of the fill tube 106 (e.g., upper end) is welded, brazed, or soldered to the fill tube support stem 112 of the sleeve 108, as shown in FIG. 3B. The welded, brazed, or soldered end of the fill tube 106 forms a seal between the fill tube 106 and the fill tube support stem 112. A standard compression fitting (e.g., Swagelock® fitting) or the like can be used to join the fill tube support stem 112 and the flange 125 and/or a gasket 122 of the manifold 110, as shown in FIG. 3C, to form a seal between the fill tube support stem 112 and the manifold 110.

In some other embodiments, an O-ring seal 132 is used between the outer diameter of the fill tube 106 and the fill tube support stem 112 to form a hermetic seal between the fill tube 106 and the fill tube support stem 112. The O-ring seal 132 may be formed of a heat and corrosion-resistant elastomer such as Viton™, Kalrez®, etc. An O-ring seal 132 does not perturb the profile or diameter of the fill tube 106, so the fill tube support stem 112 or other components can be mounted and de-mounted axially at any stage in the assembly process. Further, since the O-ring seal 132 does not constrain the fill tube 106 axially, thermal expansion during processing is much less of an issue. Since the O-ring seal 132 must be kept at a temperature below its maximum service temperature, depending on the process conditions and details of the thermal profile some means of either active or passive cooling (e.g., fans, heat sinks, water circuits) may also be incorporated. For a hermetic seal between the fill tube support stem 112 and the manifold 110, which are both formed of mechanically robust materials, the fill tube support stem 112 and the manifold 110 can be attached hermetically using any number of standard fittings or methods such as VCR®/face seal fittings, compression fittings, another O-ring seal, or the like.

The embodiments described herein provide a system and a method for real time monitoring and controlling of process pressure in a high-pressure vessel for thermal crystal growth process. The system includes a fill tube in fluid communication with a process environment of a high-pressure vessel for thermal crystal growth for the entire duration of thermal crystal growth process. Measuring process pressures also allows unambiguous leak detection that can be easily resolved as a decrease in the time-series value or slope of process pressure greater than some critical value. According to the embodiments described herein, the fill tube is also connected to a manifold which in turn can contain any number of valves, measurement devices, or even satellite components and assemblies designed to interact with the thermal crystal growth process volume in situ.

While the foregoing is directed to embodiments of the present disclosure, other and further embodiments of the disclosure may be devised without departing from the basic scope thereof, and the scope thereof is determined by the claims that follow.

1. An apparatus for high-temperature crystal growth, comprising:
a pressure vessel comprising a capsule that has an interior surface that defines an internal capsule volume;
a fill tube that comprises an outer surface and an inner surface, wherein an interior fill tube volume defined by the inner surface is in fluid communication with the internal capsule volume of the capsule;
a sleeve axially surrounding the outer surface of the fill tube, wherein the sleeve is configured to support the outer surface of the fill tube, along a length of the fill tube, during a high-temperature crystal growth process; and
a manifold comprising an interior manifold volume that is in fluid communication with the interior fill tube volume of the fill tube.

2. The apparatus of claim 1, wherein the fill tube comprises a corrosion-resistant material that is selected from a group consisting of rhenium, ruthenium, rhodium, palladium, silver, osmium, iridium, platinum, and gold, or alloy thereof.

3. The apparatus of claim 2, wherein the fill tube comprises Inconel and the inner surface of the fill tube is lined with a material that comprises silver.

4. The apparatus of claim 1, wherein
the sleeve comprises one or more cylinders, and
a radial gap between an inner surface of the sleeve and the outer surface of the fill tube is less than or equal to 0.005 inches.

5. The apparatus of claim 1, wherein
the sleeve comprises one or more half cylinders that are connected to one another over the fill tube, and
a radial gap between an inner surface of the sleeve and an outer surface of the fill tube is less than or equal to 0.005 inches.

6. The apparatus of claim 1, wherein the sleeve comprises a superalloy and the fill tube comprises a material that is selected from a group consisting of rhenium, ruthenium, rhodium, palladium, silver, osmium, iridium, platinum, and gold, or alloy thereof.

7. The apparatus of claim 1, wherein the fill tube comprises a first end and a second end that is opposite to the first end, and a temperature difference formed between the first end and the second end is greater than 400° C. during a high-temperature crystal growth process.

8. The apparatus of claim 7, wherein the fill tube is hermetically sealed at the first end directly to the manifold and at the second end to a portion of the capsule.

9. The apparatus of claim 1, further comprising a heater that is positioned over an outer surface of the sleeve, and is configured to maintain a temperature difference of no greater than 20° C. along the length of the sleeve during a high-temperature crystal growth process.

10. The apparatus of claim 1, wherein a hermetic seal is formed between the fill tube and the manifold by welding a portion of the fill tube to a portion of the manifold.

11. The apparatus of claim 1, wherein the fill tube is hermetically sealed to the sleeve and the sleeve is hermetically sealed to the manifold.

12. The apparatus of claim 11, further comprising an O-ring seal configured to form a hermetic seal between the outer surface of the fill tube and a portion of the sleeve.

13. The apparatus of claim 12, wherein the sleeve is hermetically sealed to the manifold using an O-ring seal, a face seal, or a compression seal.

14. The apparatus of claim 1, wherein the manifold comprises a pressure transducer, a fill valve, a vent valve, and a pressure gauge.

15. The apparatus of claim 1, further comprising a selective membrane, which is disposed between the manifold and an exhaust assembly or the fill tube and the manifold, wherein the selective membrane is configured to allow a first gas of a plurality gases disposed on a first side of the selective membrane to pass to an opposing side of the membrane while preventing one or more of the other plurality of gases disposed on the first side of the selective membrane from passing to the opposing side of the membrane.

16. The apparatus of claim 15, wherein the selective membrane comprises palladium, and the first gas comprises hydrogen.

17. The apparatus of claim 1, further comprising a mechanical actuator, wherein the mechanical actuator being located on an exterior of the sleeve or manifold and is configured to generate vibrations in the sleeve or manifold.

18. A supported fill tube (SFT) assembly, comprising:
a fill tube that comprises an outer surface and an inner surface, wherein an interior fill tube volume defined by the inner surface is in fluid communication with an internal volume of a sealed pressure vessel;
a sleeve axially surrounding the outer surface of the fill tube, wherein the sleeve is configured to support the outer surface of the fill tube along a length of the fill tube; and
a manifold comprising an interior manifold volume that is in fluid communication with the interior fill tube volume of the fill tube, the manifold comprising:
a fill valve that is in fluid communication with the interior manifold volume;
a selective membrane that is in fluid communication with the interior manifold volume; and
a pressure transducer that is in fluid communication with the interior manifold volume.

19. The SFT assembly of claim 18, wherein the fill tube comprises a corrosion-resistant material that is selected from a group consisting of rhenium, ruthenium, rhodium, palladium, silver, osmium, iridium, platinum, and gold, or alloy thereof.

20. The SFT assembly of claim 19, further comprising a heater positioned in thermal contact with an outer surface of the sleeve.
